(19) United States
(12) Patent Application Publication
(10) Pub. No.: US 2024/0038790 A1
(43) Pub. Date: Feb. 1, 2024

(54) Time-of-flight Pixel With Charge Storage

(71) Applicants: IFM Electronic GmbH, Essen (DE); PMDTechnologies AG, Siegen (DE)

(72) Inventors: Matthias Franke, Haiger (DE); Robert Rössler, Berlin (DE); Gerrit Lükens, Siegen (DE); Ana-maria Teodoreanu, Siegen (DE)

(73) Assignees: IFM Electronic GmbH, Essen (DE); PMDTechnologies AG, Siegen (DE)

(21) Appl. No.: 18/265,255

(22) PCT Filed: Nov. 2, 2021
(86) PCT No.: PCT/EP2021/080373

§ 371 Date: Jun. 4, 2023

(30) Foreign Application Priority Data
Dec. 9, 2020 (DE) 10 2020 132 868.0

(51) Int. Cl. H01L 27/146; G01S 7/481

(52) U.S. Cl. CPC H01L 27/14607; G01S 7/4816; H01L 27/14625

(57) ABSTRACT

The invention relates to a light transit time pixel comprising —at least one modulation gate (GA, GB) which has a photoactive region (FAB) and a storage region (MA, MB), said storage region (MA, MB) having a locally increased n-type doping below the modulation gate (GA, GB) and delimiting the photoactive region (FAB) of the modulation gate (GA, GB), —at least one transfer gate (TXA, TXB) which adjoins the storage region (MA, MB) of the modulation gate (GA, GB), —at least one reading diode (DA, DB) which follows the transfer gate (TXA, TXB), —at least one drain gate (DG) which adjoins one side of the light-sensitive region (FAB) of the modulation gate (GA, GB), and —at least one drain diode (DD) which follows the drain gate (DG).

The invention relates to a time-of-flight pixel with a charge storage below the modulation gates and a time-of-flight sensor comprising corresponding pixels.

The time-of-flight sensor according to the invention is used in particular in time-of-flight camera systems which obtain distances from the phase shift of emitted and received radiation. As time-of-flight or 3D cameras in particular PMD cameras with photomixing detectors (PMD), such as those described in DE 197 04 496 A1 are suitable.

It is an object of the invention to reduce the space requirement of a time-of-flight pixel in the time-of-flight sensor.

The time-of-flight pixel according to the invention solves this object and enables the demodulation and storage of the photogenerated charge carriers under a single photogate to be carried out. This results in a significant reduction of the space requirement.

The figures schematically show:

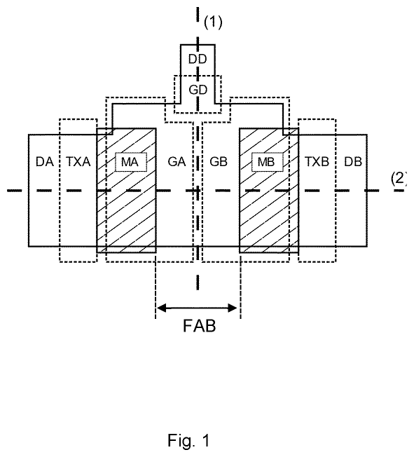

FIG. 1 a top view of a pixel structure according to the invention:

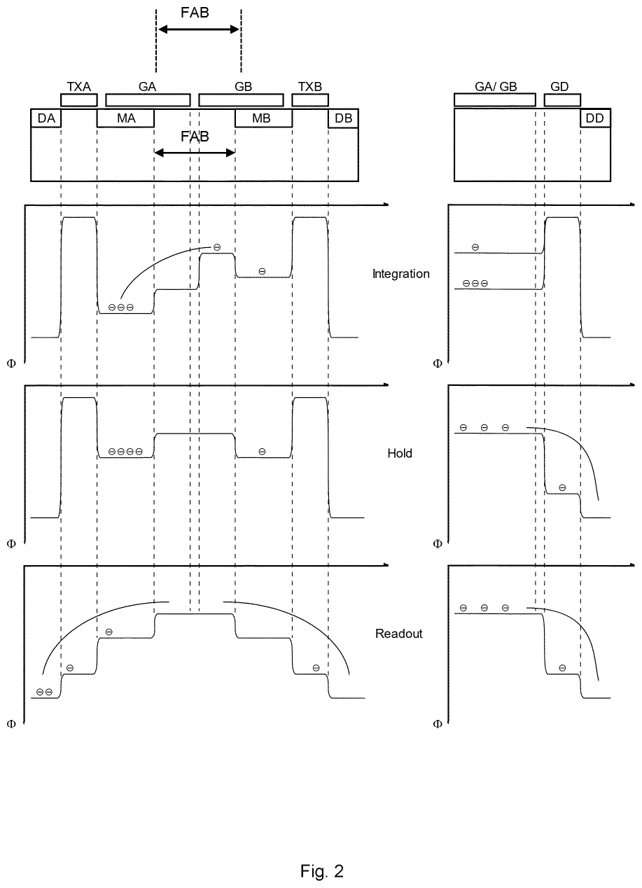

FIG. 2 a cross-section of the pixel structure with potential distributions;

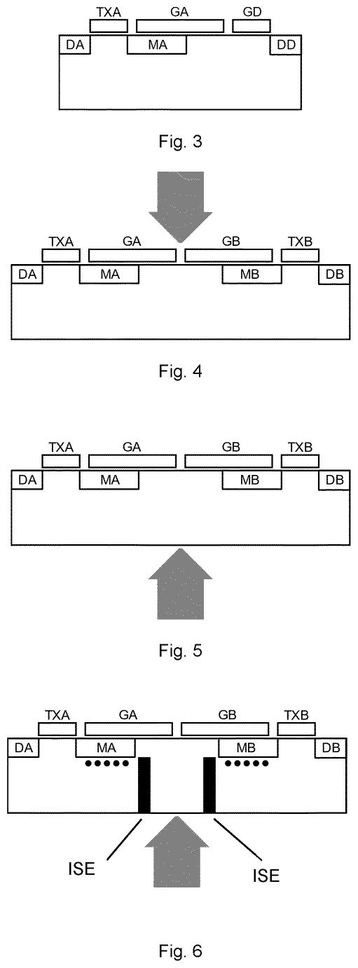

FIG. 3 a further embodiment of the structure according to the invention;

FIG. 4 an embodiment for front side illumination;

FIG. 5 an embodiment for back side illumination;

FIG. 8 an embodiment for back side illumination with optical isolators;

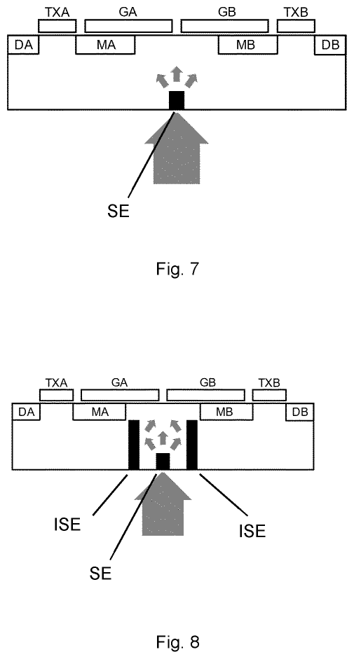

FIG. 7 an embodiment for back side illumination with scattering elements; and

FIG. 8 an embodiment for back side illumination with optical isolators and scattering elements.

The idea according to the invention, as sketched in FIG. 1, is that the charges photogenerated in the silicon are deflected by a modulated voltage on the photogates GA and GB and the concomitant formation of the known charge carrier swing in the direction of the storage regions MA and MB, respectively, and are collected there. The storage regions MA, MB are configured in such a way that the charge carriers permanently, i.e. independently of the voltage applied to the photogates GA. GB remain in the storage regions MA, MB as long as the corresponding transfer gate TXA or TXB has a low potential. In case a transfer gate TXA TXB has a high potential and at the same time the corresponding photogate has a low potential, the charges collected in the storage region are discharged towards the readout diode DA, DB.

In addition, a drain gate GD with attached drain diode DD allows the defined suppression of the integration below the storage regions MA, MB.

On a semiconductor substrate, which has a suitable doping of p- or n-type, two photogates GA, GB form a photoactive area FAB disposed centrally in a time-of-flight pixel. Below the photogates GA, GB and bounding the photoactive area FAB storage regions MA and MB are arranged in the semiconductor substrate, wherein the photogates GA, GB only partially cover the storage regions MA, MB.

Adjacent to the memory regions MA, MB the respective transfer gates TXA and TXB are disposed, which in turn are adjacent to the readout diodes DA and DB. In a vertical or perpendicular direction to photogate GA, GB, transfer gate TXA, TXB and diodes DA, DB, a drain gate (GD) is arranged, which connects the mixer area or the photoactive area FAB of the photogates GA, GB with a drain diode DD (discard node) in a switchable manner.

The storage regions MA, MB are preferably produced partially below the photogates GA, GB with the aid of an enhanced n-type implantation. These implantations lead to a local increase of the electrostatic potential below the photogates GA, GB. These areas can be used as storage region MA, MB for intermediate storage of the demodulated photoelectrons.

Thus, a double functionality is achieved with the photogates GA, GB: On the one hand the demodulation of the photogenerated charge carriers and on the other hand the intermediate storage of these charge carriers, in order to achieve a functionality according to the principle of correlated double sampling with simultaneous global electronic aperture (global shutter). The structure can be used both for a front side illumination FSI as well as for a back side illumination BSI of the pixel.

FIG. 2 shows the structural and potential sections through a time-of-flight sensor or a time-of-flight pixel according to the invention when applying application-typical voltages. In addition to the structural section, the potential sections for the following modes are shown: a) integration, b) hold, and c) readout.

### a) Integration Mode.

During integration the transfer gates TXA and TXB are kept at low potential, thus separating the storage regions MA and MB from the readout diodes DA and DB. Drain gate GD is also at low potential and separates the drain contact from the mixer area or the photoactive area FAB. The photogates GA and GB form the sufficiently known charge carrier swing. The correspondingly demodulated photogenerated charge carriers enter the storage regions MA and MB, respectively. In the further course of the integration phase, the charge carriers stored there can escape neither in the direction of the readout diode DA, DB nor in the direction of the photoactive area FAB. The storage capability of the storage regions MA, MB is thus independent of the voltage applied to the photogates GA, GB. Thus, there is a continuous integration of charge carriers in the storage regions MA, MB during the integration phase.

### b) Hold Mode:

In the hold mode both photogates GA, GB are kept at low potential and the transfer gates TXA, TXB decouple the storage regions MA, MB from the readout diodes DA, DB. In order to prevent further integration of charge carriers in the storage regions, the drain gate GD is now switched to a high potential, resulting in a direct connection of the mixer region GA, GB with the drain diode DD. The photogenerated charge carriers are now discharged in the direction of the drain diode DD, i.e. they are no longer available for further integration in the storage regions MA, MB.

### c) Readout Mode:

The readout mode is used to transfer the charge carriers integrated below the storage regions MA, MB in the direction of the readout diodes DA and DB. For this purpose, photogates GA and GB are kept at low potential. The drain gate GD is also kept at high potential and discharges all charge carriers photogenerated during the readout mode towards the drain diode DD.

The transfer gates TXA and TXB are now switched to a high potential, resulting in a formation of a potential gradient in the direction of the readout diodes DA, DB. This causes the charges stored in the storage regions MA, MB to flow towards the readout diodes DA, DB. With an appropriate timing, the readout can be performed as a noise-reduced correlated double sampling, CDS.

FIG. 3 shows an implementation of the time-of-flight pixel comprising only one diode node DA (one tap). In this embodiment, one of the two readout channels A or B is dispensed with. In the present case, the pixel comprises a photogate GA and a storage node for the A channel while the B channel is formed with a drain gate GD and drain diode DD. Accordingly, the modulation signal is provided at the A channel photogate GA and the complementary modulation signal is provided at the drain gate GD. The photogenerated charge carriers are thus either integrated in the storage region MA or discharged via the drain diode DD.

In principle, designs with more than two diode nodes are also conceivable.

FIG. 4 shows an illumination of the time-of-flight pixel according to the invention from the front side (front side illumination, FSI) and FIG. 5 shows an illumination from the back side (back side illumination, BSI).

FIG. 6 shows an embodiment comprising a storage region MA, MB optically isolated for the back side illumination BSI, in which trenches or buried reflectors ISO are used for optical isolation.

FIG. 7 shows a variant comprising a scattering element SR on the back side of the time-of-flight pixel. In this embodiment, one or more scattering elements SR, e.g. trenches or pyramid structures, can be provided in order to increase the quantum efficiency.

The scattering elements SR can be combined with optical isolation elements ISO, as shown in FIG. 8, in order to optically isolate the storage regions MA, MB.

### LIST OF REFERENCE SYMBOLS

GA, GB photogates A and B
MA, MB storage regions A and B
TXA, TXB transfer gates A and B
DA, DB readout diodes A and B
GD drain gate
DD drain diode

1: A time-of-flight pixel, comprising at least one modulation gate (GA, GB) comprising a photoactive area (FAB) and a storage region (MA, MB),
wherein the storage region (MA, MB) has a locally enhanced doping of the n-type below the modulation gate (GA, GB) and delimits the photoactive area (FAB) of the modulation gate (GA, GB);
at least one transfer gate (TXA TXB) adjoining the storage region (MA, MB) of the modulation gate (GA, GB);
at least one readout diode (DA, DB) following the transfer gate (TXA TXB);
at least one drain gate (DG) adjoining one side of the photoactive area (FAB) of the modulation gates (GA, GB); and
at least one drain diode (DD) following the drain gate (DG).

2: A time-of-flight pixel according to claim 1, which is configured for backside illumination, comprising a scattering element (SE) for scattering light incident on a back side of the time-of-flight pixel.

3: A time-of-flight pixel according to claim 2, wherein the scattering elements (SE) are formed as trenches or pyramid-like structures.

4: A time-of-flight pixel according to claim 1, wherein the storage regions (MA, MB) are protected from direct incidence of light from the back side by optically insulating structures (ISO).

5: A time-of-flight sensor comprising a time-of-flight pixel according to claim 1.

6: A time-of-flight camera or time-of-flight camera system comprising the time-of-flight sensor according to claim 5.
